(19) United States
(12) Patent Application Publication
(10) Pub. No.: US 2026/0282855 A1
(43) Pub. Date: Sep. 17, 2026

(54) METHOD OF FORMING SEMICONDUCTOR DEVICE

(71) Applicant: NANYA TECHNOLOGY CORPORATION, New Taipei City (TW)

(72) Inventor: Tai-Wei Chen, New Taipei City (TW)

(73) Assignee: NANYA TECHNOLOGY CORPORATION, New Taipei City (TW)

(21) Appl. No.: 19/078,307

(22) Filed: Mar. 13, 2025

(51) Int. Cl. H01L 21/74; H01L 21/306; H01L 21/762; H01L 21/768

(52) U.S. Cl. CPC H10W 15/00; H10P 50/00; H10W 10/0124; H10W 10/13; H10W 15/01; H10W 20/056

(57) ABSTRACT

A method of forming a semiconductor device includes the following steps. A trench is formed in a semiconductor layer. A surface treatment is performed to reduce a surface roughness of the trench. An oxide layer is formed in the trench.

### BACKGROUND

### Technical Field

The present invention relates to a semiconductor device, and in particular to a method of forming a semiconductor device.

### Description of Related Art

In semiconductor industry, gate structures may be formed in the semiconductor substrate as buried gate structures. To form the buried gate structures, trenches are first formed in the semiconductor substrate. Generally, surfaces of the trenches are not smooth, which affects the gate oxide layer subsequently formed. The poorly formed gate oxide layer may result in a high risk of the gate induced drain leakage and lower the performance of the device. Besides, during the forming of the trenches, some charges may be trapped in the semiconductor layer, and theses trapped charges may cause crosstalk between the adjacent gate structures and lower the performance of the device. Therefore, it is necessary to find a solution to eliminate the aforementioned problem.

### SUMMARY

The present invention provides a method of forming a semiconductor device, which can improve the performance of the semiconductor device.

The method of forming the semiconductor device of the present invention includes the following steps. A trench is formed in a semiconductor layer. A surface treatment is performed to reduce a surface roughness of the trench. An oxide layer is formed in the trench.

In an embodiment of the method of the present invention, the surface treatment is a hydrogenation treatment.

In an embodiment of the method of the present invention, the surface treatment includes performing a rapid thermal anneal process with hydrogen gas.

In an embodiment of the method of the present invention, a process temperature of the surface treatment is in a range of 500 degrees Celsius to 900 degrees Celsius.

In an embodiment of the method of the present invention, a process duration of the surface treatment is in a range of 5 seconds to 90 seconds.

In an embodiment of the method of the present invention, the surface roughness of the trench is reduced by 40% to 60% after performing the surface treatment.

In an embodiment of the method of the present invention, after performing the surface treatment, a Si—H bond is formed at a surface of the trench.

In an embodiment of the method of the present invention, the oxide layer is formed by a thermal oxidation process.

In an embodiment of the method of the present invention, forming the trench in the semiconductor layer includes the following steps. A hard mask layer is formed on the semiconductor layer. The hard mask layer is patterned to expose a portion of a top surface of the semiconductor layer. Using the patterned hard mask layer as an etching mask, a portion of the semiconductor layer is removed to form the trench.

In an embodiment of the method of the present invention, the method further includes following steps. A word line structure is formed in the trench. Source/drain regions are formed in the semiconductor layer.

Based on the above, the semiconductor device includes a buried word line structure in the semiconductor layer and an oxide layer between the word line structure and the semiconductor layer. Since a surface treatment to a trench of the semiconductor layer is performed before the oxide layer is formed, the oxide layer is uniformly formed and has a smooth surface, as well as the trapped charges in the semiconductor layer are reduced, such that the performance of the semiconductor device can be improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 6 are schematic cross-sectional views of a method of forming a semiconductor device according to an embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

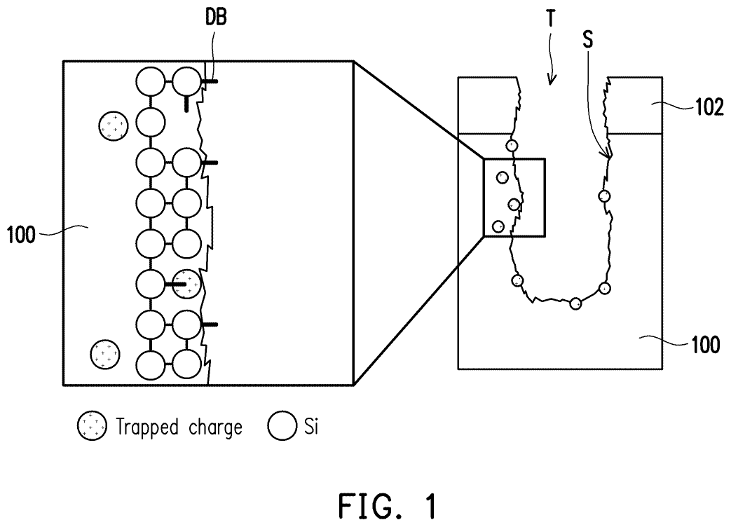

FIG. 1 to FIG. 6 are schematic cross-sectional views of a method of forming a semiconductor device 10 according to an embodiment of the present invention.

Referring to FIG. 1, a trench T is formed in the semiconductor layer 100. For example, first, a hard mask layer 102 is formed on the semiconductor layer 100 by physical vapor deposition process, chemical vapor deposition process, atom layer deposition process or other suitable methods. By photolithography and etching processes, the hard mask layer 102 is patterned to expose a portion of a top surface of the semiconductor layer 100. In some embodiments, the semiconductor layer 100 includes silicon, germanium, silicon germanium, silicon carbide or other suitable semiconductor materials. In some embodiments, the semiconductor layer 100 may be an epitaxial layer formed on a semiconductor substrate. In some embodiments, the hard mask layer 102 includes silicon nitride or other suitable materials.

Then, using the hard mask layer 102 as an etching mask, a portion of the semiconductor layer 100 is removed by an etching process to form the trench T. In some embodiments, the etching process is a dry etching process, such as a plasma etching process, a reactive ion etching process or the like. In some embodiments, the etch gas for the trench etching process includes CF₄, SF₆, XeF₂, CCl₄, radicals or ions thereof or the like. Although only one trench T is illustrated in FIG. 1, it is appreciated that the number of the trench T is not limited and can be adjusted according to the actual need.

In some embodiments, during the forming of the trench T, the etching process damages the semiconductor layer 100 and forms defects (such as dangling bonds, trapped charges or the like) in the semiconductor layer 100. The generation of the dangling bonds DB may make the lattice of the semiconductor layer 100 near the trench T fragile and a surface S of the trench T rough. A surface roughness of the trench T may affect the formation of the oxide layer subsequently formed. When the surface roughness of the trench T is getting higher, the oxide layer subsequently formed may have a rough surface and may not be uniformly formed on the surface S of the trench T and thus a risk of current leakage of the semiconductor device 10 may become higher. In addition, the trapped charges may be radicals or ions trapped or remained in the semiconductor layer 100 during or after the forming of the trench T, or intrinsically present in the semiconductor layer 100. The trapped charges in the semiconductor layer 100 may induce crosstalk and interfere the signal transmission of the semiconductor device 10.

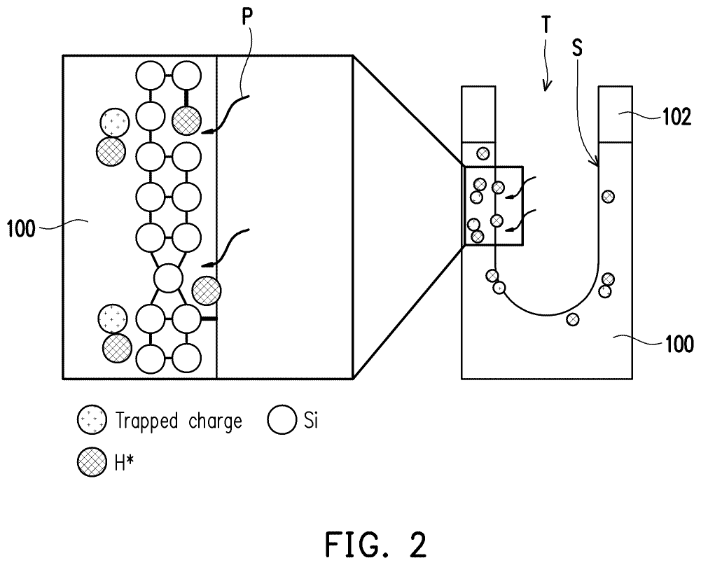

Referring to FIG. 2, a surface treatment P is performed to reduce a surface roughness of the trench T. The surface treatment P is a hydrogenation treatment. In some embodiments, the surface treatment P is a rapid thermal hydrogenation treatment. In some embodiments, a rapid thermal anneal process with hydrogen gas is performed to the trench T. For example, a gas flow including the hydrogen gas is introduced to the system at the same time when the rapid thermal anneal process is performed. In some embodiments, the gas flow is a pure hydrogen gas flow. That is, the gas flow includes almost a 100 vol % of hydrogen gas. In some embodiments, a flow rate of the gas flow is in a range of 4 standard liter per minute (slm) to 16 slm.

In some embodiments, before performing the surface treatment, an inert gas flow may be introduced to the trench T to remove impurities on the surface S of the trench T. In some embodiments, the inert gas flow includes nitrogen gas, argon, or other suitable inert gas. In some embodiments, after performing the surface treatment, an additional inert gas flow may be introduced to the trench T for cooling aid.

During the rapid thermal anneal process, the hydrogen gas is dissociated to hydrogen radicals (H*). The hydrogen radicals may contact the surface S of the trench T and repair the dangling bonds DB to form Si—H bonds, plus silicon migration may occur under the thermal environment, which stabilizes the lattice arrangement of the semiconductor layer 100 and also smoothens the surface S of the trench T.

In some embodiment, the surface roughness of the trench T is reduced by 40% to 60% after performing the surface treatment P. For example, the surface roughness of the trench is around 0.15 nm to 0.25 nm or more before performing the surface treatment P, and the surface roughness of the trench becomes around 0.09 nm to 0.11 nm after performing the surface treatment P. Since the surface roughness of the trench T is reduced, it advantages the uniformity and roughness of the oxide layer subsequently formed.

In some embodiment, a portion of the hydrogen radicals may diffuse into the semiconductor layer 100 to neutralize the trapped charges. Since the trapped charges in the semiconductor layer 100 is neutralized, the trapped charges in the semiconductor layer 100 are reduced, which may mitigate the crosstalk induced by the trapped charges. In some embodiment, the neutralized trapped charges may be beneficial to the stabilization of the oxide layer subsequently formed.

In some embodiment, a process temperature of the surface treatment P is in a range of 500 degrees Celsius to 900 degrees Celsius to facilitate the silicon migration and the hydrogen dissociation.

In some embodiment, a process duration of the surface treatment P is in a range of 5 seconds to 90 seconds to have low thermal budget while the surface S of the trench T is smoothed.

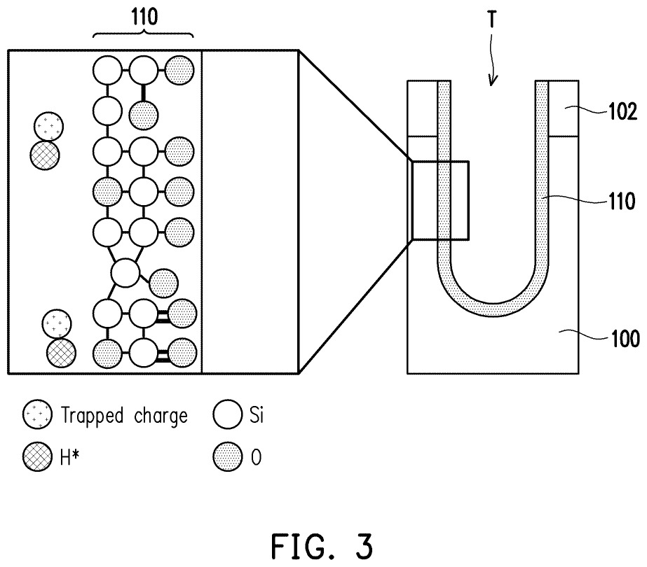

Referring to FIG. 3, an oxide layer 110 is formed in the trench T. For example, the oxide layer 110 is formed by a thermal oxidation process. That is, the surface S of the trench T is oxidized to form the oxide layer 110. In an embodiment where the semiconductor layer 100 includes silicon, the silicon is oxidized to form silicon oxide. That is, the oxide layer 110 is a silicon oxide layer. Since the surface of the trench T is smoothened by the surface treatment P, the oxide layer 110 could be uniformly formed in the trench T and has a smooth surface, and thereby a risk of current leakage of the semiconductor device 10 is reduced.

In some embodiments, the Si—H bonds may be broken during the thermal oxidation process, and the hydrogen atoms may be released into the environment. In other embodiments, a few Si—H bonds may exist in the semiconductor layer 110 after the forming of the oxide layer 110.

In some embodiments, a process temperature of the thermal oxidation process is between 800° C. and 1100° C., but it is not limited.

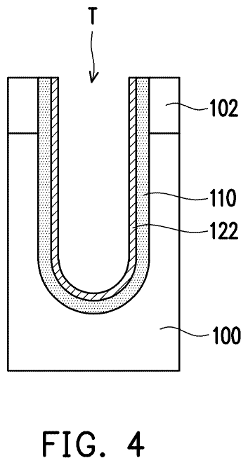

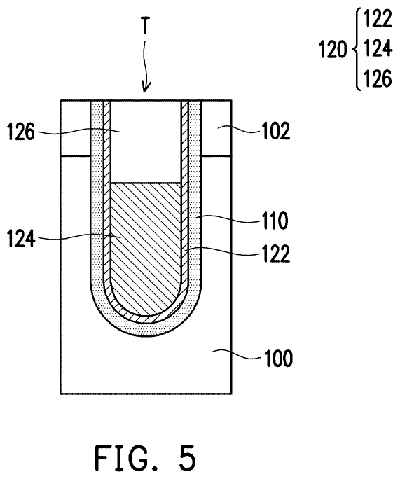

Referring to FIG. 4 and FIG. 5, a word line structure 120 (also called a gate structure 120) is formed in the trench T. For example, in FIG. 4, a barrier layer 122 is formed in the trench T on the oxide layer 110. Then, in FIG. 5, a conductive layer 124 is formed in the trench T, and a capping layer 126 is formed on the conductive layer 124 in the trench T. The barrier layer 122, the conductive layer 124 and the capping layer 126 collectively forms the word line structure 120.

In some embodiments, the barrier layer 122 is conformally formed by a physical vapor deposition (such as sputtering or the like) process or other suitable methods. In some embodiments, a material of the barrier layer 122 includes titanium nitride, tantalum nitride, tantalum or other suitable materials to prevent metal diffusion to the semiconductor layer 110.

In some embodiments, the formation of the conductive layer 124 includes the following steps. A conductive material is formed in the trench T by physical vapor deposition process, chemical vapor deposition process, atom layer deposition process or other suitable methods, and an etching process is performed to remove a portion of the conductive material and the remaining conductive material forms the conductive layer 124. In some embodiments, the conductive layer 124 may be a single layer structure or a multilayer structure. In some embodiments, a material of the conductive layer 124 includes poly silicon, metal (such as copper, tungsten, aluminum, titanium or the like), metal nitride or other suitable conductive materials.

In some embodiments, the formation of the capping layer 126 includes the following steps. An insulation material is formed in the trench T and on the hard mask layer 102 by physical vapor deposition process, chemical vapor deposition process, atom layer deposition process or other suitable methods, and a planarization process (such as chemical mechanical grinding process or the like) is performed to remove excess insulation material to expose the top surface of the hard mask layer 102, and thereby the capping layer 126 is formed. In some embodiments, a material of the capping layer 126 includes silicon oxide, silicon nitride, silicon oxynitride or other suitable insulation materials.

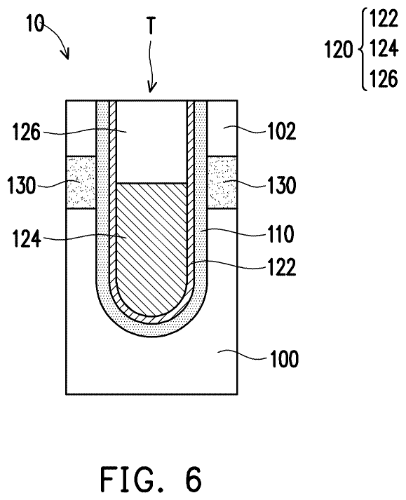

Referring to FIG. 6, source/drain regions 130 are formed in the semiconductor layer 100. The source/drain regions 130 is formed by an ion implantation process. The source/drain regions 130 are located at opposite sides of the trench and adjacent to the top surface of the semiconductor layer 100. The word line structure 120 and the source/drain regions 130 collectively forms a transistor in the semiconductor layer 100.

In some embodiments, the semiconductor device 10 may be a memory device, but it is not limited. In some embodiments, a capacitor structure (not shown) may be formed over the semiconductor layer 100 and electrically connected to the source/drain region 130 of the transistor to form a memory cell on the semiconductor layer 100.

Based on the above, the semiconductor device 10 is substantially formed. The semiconductor device 10 includes a buried word line structure 120 in the semiconductor layer 100 and an oxide layer 110 between the word line structure 120 and the semiconductor layer 100. Since a surface treatment P to a trench T of the semiconductor layer 100 is performed before the oxide layer 110 is formed, the oxide layer 110 is uniformly formed and has a smooth surface, as well as the trapped charges in the semiconductor layer 100 are reduced, such that the performance of the semiconductor device 10 can be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of forming a semiconductor device, comprising:
forming a trench in a semiconductor layer;
performing a surface treatment to reduce a surface roughness of the trench; and
forming an oxide layer in the trench.

2. The method of claim 1, wherein the surface treatment is a hydrogenation treatment.

3. The method of claim 2, wherein the surface treatment comprises:
performing a rapid thermal anneal process with hydrogen gas.

4. The method of claim 1, wherein a process temperature of the surface treatment is in a range of 500 degrees Celsius to 900 degrees Celsius.

5. The method of claim 1, wherein a process duration of the surface treatment is in a range of 5 seconds to 90 seconds.

6. The method of claim 1, wherein the surface roughness of the trench is reduced by 40% to 60% after performing the surface treatment.

7. The method of claim 1, wherein after performing the surface treatment, a Si—H bond is formed at a surface of the trench.

8. The method of claim 1, wherein the oxide layer is formed by a thermal oxidation process.

9. The method of claim 1, wherein forming the trench in the semiconductor layer comprises:
forming a hard mask layer on the semiconductor layer;
patterning the hard mask layer to expose a portion of a top surface of the semiconductor layer; and
using the patterned hard mask layer as an etching mask, removing a portion of the semiconductor layer to form the trench.

10. The method of claim 1, further comprising:
forming a word line structure in the trench; and
forming source/drain regions in the semiconductor layer.
